(19) United States
(12) Patent Application Publication
(10) Pub. No.: US 2025/0008823 A1
(43) Pub. Date: Jan. 2, 2025

(54) BARRIER ENCAPSULATION FOR ORGANIC LIGHT-EMITTING DIODES

(71) Applicant: Applied Materials, Inc., Santa Clara, CA (US)

(72) Inventors: Zongkai WU, Santa Clara, CA (US); Pei Chia CHEN, Tokyo (JP); Wen-Hao WU, San Jose, CA (US); Jungmin LEE, Santa Clara, CA (US); Chung-chia CHEN, Hsinchu City (TW); Yu-Hsin LIN, Zhubei City (TW); Kevin CHEN, Santa Clara, CA (US); Wenhui LI, Santa Clara, CA (US); Yu-Min WANG, Tainan City (TW); Lai ZHAO, Campbell, CA (US); Soo Young CHOI, Fremont, CA (US)

(21) Appl. No.: 18/594,527

(22) Filed: Mar. 4, 2024

Related U.S. Application Data
(60) Provisional application No. 63/510,399, filed on Jun. 27, 2023.

(51) Int. Cl. H10K 59/80; H10K 59/12; H10K 59/122

(52) U.S. Cl. CPC H10K 59/8731; H10K 59/1201; H10K 59/122

(57) ABSTRACT

Sub-pixel circuits and methods of forming sub-pixel circuits that may be utilized in a display, such as an organic light-emitting diode (OLED) display, are provided. In one example, a sub-pixel includes a substrate, adjacent overhang structures, an anode, an OLED material, a cathode, an encapsulation layer stack. The encapsulation layer stack includes a first layer, a second layer disposed over the first layer, and a third layer. The first layer and the second layer have a first portion disposed over the cathode, a second portion disposed over a sidewall of each overhang structure, and a third portion disposed under an underside surface of an extension of each overhang structure. A gap is defined by contact of the first portion of the second layer and the third portion of the second layer. The third layer is disposed over the second layer outside of the gap.

### CROSS-REFERENCE TO RELATED APPLICATIONS

This application claims priority to U.S. Provisional Patent Application No. 63/510,399, filed Jun. 27, 2023, the entirety of which is herein incorporated by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. OLED devices are classified as top emission devices if light emitted passes through a lid that is added following the fabrication of the device. OLEDs are used to create display devices in many electronics today. It is desirable for display devices to shrink in size while providing higher resolution.

OLED pixel patterning is currently based on a process that restricts panel size, pixel resolution, and substrate size. Rather than utilizing a fine metal mask, it may be desirable for photolithography to be used to pattern pixels. Currently, OLED pixel patterning requires lifting off organic material after the patterning process. When lifted off, the organic material may leave behind particles that can disrupt OLED performance. Accordingly, what is needed in the art are sub-pixel circuits and methods of forming sub-pixel circuits that may be utilized in a display such as an organic OLED display.

### SUMMARY

In an embodiment, a sub-pixel is provided. The sub-pixel includes a substrate, adjacent overhang structures, an anode, an organic light-emitting diode (OLED) material, a cathode disposed over the OLED material, and an encapsulation layer stack. The adjacent overhang structures define the sub-pixel. The OLED material is disposed over the anode. The cathode is disposed over the OLED material. The encapsulation layer stack has a first layer, a second layer disposed over the first layer, and a third layer. The first layer and the second layer have a first portion disposed over the cathode, a second portion disposed over a sidewall of each overhang structure, and a third portion disposed under an underside surface of an extension of each overhang structure. A gap is defined by contact of the first portion of the second layer and the third portion of the second layer. The third layer is disposed over the second layer outside of the gap.

In an embodiment, a device is provided. The device includes a substrate, adjacent overhang structures, an anode, an organic light-emitting diode (OLED) material, a cathode, and an encapsulation layer stack. The OLED material is disposed over the anode. The cathode is disposed over the OLED material. The encapsulation layer stack has a first layer, a second layer disposed over the first layer, and a third layer. The first layer and the second layer have a first portion disposed over the cathode, a second portion disposed over a sidewall of each overhang structure, and a third portion disposed under an underside surface of an extension of each overhang structure. A gap is defined by contact of the first portion of the second layer and the third portion of the second layer. The third layer is disposed over the second layer outside of the gap.

In an embodiment, a method of forming a sub-pixel circuit is provided. The method includes depositing a first layer of a first material over a first organic light-emitting diode (OLED) material of the sub-pixel circuit, depositing a second layer of a second material over the first layer, depositing a resist material over the sub-pixel circuit, patterning and removing a portion of the resist material, removing a first portion of the first layer and a first portion of the second layer exposed by the resist material in a well of a sub-pixel of the sub-pixel circuit, depositing a second OLED material in the well, depositing a third layer of the first material over the second OLED material in the well, depositing a fourth layer of the second material over the third layer, and depositing a fifth layer of a third material over a second portion of the first layer and over a second portion of the second layer. The first layer and the third layer of the first material may be deposited using a plasma-enhanced chemical vapor deposition (PECVD) process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit, according to embodiments.

FIG. 1B is a schematic, top sectional view of a sub-pixel circuit having a dot-type architecture, according to embodiments.

FIG. 1C is a schematic, cross-sectional view of a sub-pixel circuit having a line-type architecture, according to embodiments.

FIG. 2A is a schematic, cross-sectional view of an overhang structure of a sub-pixel circuit, according to embodiments.

FIG. 2B is a schematic, cross-sectional view of an overhang structure of a sub-pixel circuit with a first layer of an encapsulation layer stack, according to embodiments.

FIG. 2C is a schematic, cross-sectional view of an overhang structure of a sub-pixel circuit with a first layer and a second layer of an encapsulation layer stack, according to embodiments.

FIG. 2D is a schematic, cross-sectional view of an overhang structure of a sub-pixel circuit with a first layer and a second layer of an encapsulation layer stack and a layer of resist material, according to embodiments.

FIG. 3 is a schematic, cross-sectional view of a sub-pixel circuit 300 according to embodiments.

FIG. 4A is an enlarged, schematic, cross-sectional view of the overhang structure of the sub-pixel circuit shown in FIG. 3.

FIG. 4B is an enlarged schematic, cross-sectional view of the overhang structure of the sub-pixel circuit shown in FIGS. 3 and 4A, but without the second layer and the third layer.

FIG. 4C is a schematic, cross-sectional view of the overhang structure of the sub-pixel circuit shown in FIGS. 3, 4A, and 4B, but without the third layer.

FIG. 4D is a schematic, cross-sectional view of an overhang structure of a sub-pixel circuit with a first layer and a second layer of an encapsulation layer stack and a layer of resist material.

FIG. 5 is a flow diagram of a method for forming sub-pixel circuits according to embodiments.

FIGS. 6A-6H are schematic, cross-sectional views of a substrate during a method of forming a sub-pixel according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

Each of the embodiments described herein of the sub-pixel circuit include a plurality of sub-pixels with each of the sub-pixels defined by adjacent overhang structures that are permanent to the sub-pixel circuit. While the Figures depict two or three sub-pixels with each sub-pixel defined by adjacent overhang structures, the sub-pixel circuit of the embodiments described herein may include a plurality of sub-pixels, such as three or more sub-pixels. Each sub-pixel has OLED material configured to emit a white, red, green, blue or other color light when energized. For example, the OLED material of a first sub-pixel emits a red light when energized, the OLED material of a second sub-pixel emits a green light when energized, and the OLED material of a third sub-pixel emits a blue light when energized.

The overhang structures are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathodes. In one embodiment, the HIL layer has a greater conductivity than the HTL layer. In another embodiment, the HIL layer has a greater energy level than the HTL layer. In some instances, layers of an encapsulation layer stack may be disposed via evaporation deposition. In embodiments including one or more capping layers, the capping layers are disposed between the cathode and the encapsulation layer stack. The overhang structures and the evaporation angle set by the evaporation source define the deposition angles, i.e., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer stack (which may be formed from one or more layers) of a respective sub-pixel is disposed over the cathode with the encapsulation layer stack extending under at least a portion of each of the adjacent overhang structures. The encapsulation layer stack of each sub-pixel contacts at least a portion of a sidewall of each of the adjacent overhang structures. The encapsulation layer stack can be varied by thickness, composition, and deposition method depending on the OLED materials deposited on the sub-pixels.

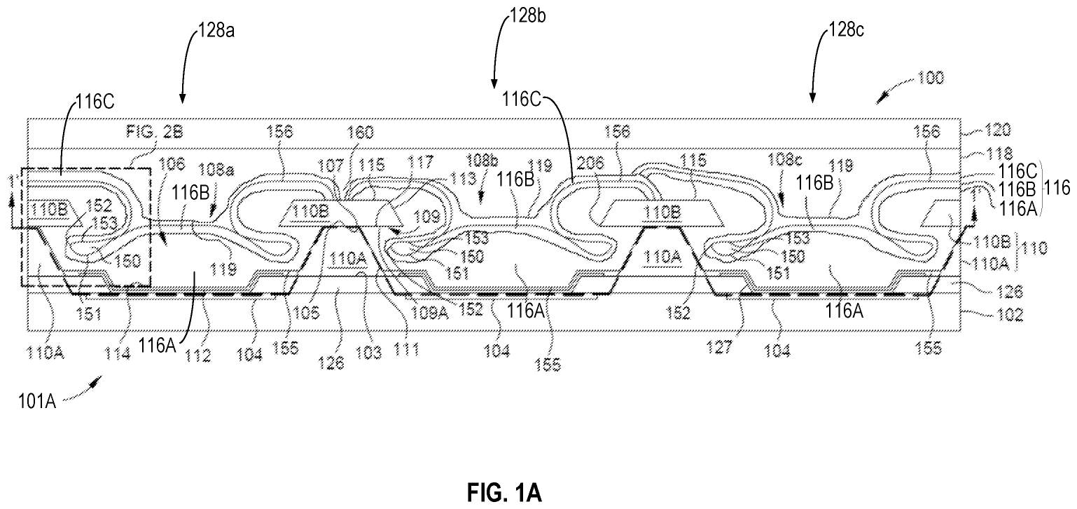

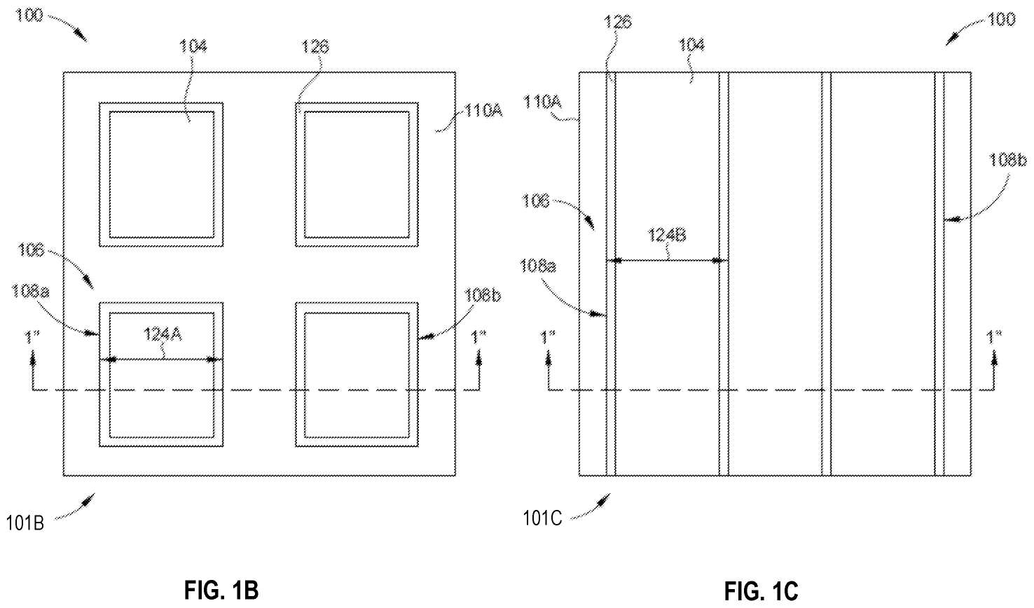

FIG. 1A is a schematic, cross-sectional view of a sub-pixel circuit 100 having arrangement 101A. The cross-sectional view of FIG. 1A is taken along section lines 1,-1, of FIGS. 1B and 1C.

The sub-pixel circuit 100 includes a substrate 102. In an embodiment, metal-containing layers 104 may be patterned on the substrate 102 and may be defined by adjacent pixel-defining layer (PDL) structures 126 disposed on the substrate 102. In one embodiment, the metal-containing layers 104 are pre-patterned on the substrate 102. E.g., the substrate 102 is a pre-patterned indium tin oxide (ITO) glass substrate. The metal-containing layers 104 are configured to operate as anodes of respective sub-pixels. The metal-containing layers 104 include, but are not limited to, chromium, titanium, gold, silver, copper, aluminum, ITO, a combination thereof, or other suitably conductive materials.

In an embodiment, PDL structures 126 may be disposed on the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, a silicon oxide (SiO₂) material, a silicon nitride (Si₃N₄) material, a silicon oxynitride (Si₂N₂O) material, a magnesium fluoride (MgF₂) material, or combinations thereof. Adjacent PDL structures 126 may define wells 128 of respective sub-pixels 108 and expose the anode (i.e., metal-containing layer 104) of the respective sub-pixels 108 of the sub-pixel circuit 100.

The sub-pixel circuit 100 has a plurality of sub-pixels 106 including at least a first sub-pixel 108a, a second sub-pixel 108b, and a third sub-pixel 108c. While the Figures depict the first sub-pixel 108a, the second sub-pixel 108b, and the third sub-pixel 108c, the sub-pixel circuit 100 of the embodiments described herein may include three or more sub-pixels 106, such as a fourth and a fifth sub-pixel. Each sub-pixel 106 has an organic light-emitting diode (OLED) material 112 configured to emit a white, red, green, blue or other color light when energized. E.g., the OLED material 112 of the first sub-pixel 108a emits a red light when energized, the OLED material of the second sub-pixel 108b emits a green light when energized, the OLED material of a third sub-pixel 108c emits a blue light when energized, and the OLED material of a fourth sub-pixel and a fifth sub-pixel emits another color light when energized.

In an embodiment, overhang structures 110 may be disposed on an upper surface 103 of each of the PDL structures 126. The overhang structures 110 are permanent to the sub-pixel circuit. The overhang structures 110 further define each sub-pixel 106 of the sub-pixel circuit 100. The overhang structures 110 include at least a second structure 110B disposed over a first structure 110A. In one embodiment, the second structure 110B is disposed on the first structure 110A. The first structure 110A may be disposed over the upper surface 103 of the PDL structure 126. In one embodiment, the first structure 110A is disposed on the upper surface 103 of the PDL structure 126. Each overhang structure 110 includes adjacent overhangs 109. The adjacent overhangs 109 are defined by a top extension 109A of the second structure 110B extending laterally past a sidewall 111 of the first structure 110A.

The second structure 110B includes one of a non-conductive material, an inorganic material, or a metal-containing material. The first structure 110A includes a non-conductive material, an inorganic material, or a metal-containing material. The non-conductive material includes, but it not limited to, an inorganic silicon-containing material. For example, the silicon-containing material includes oxides or nitrides of silicon, or combinations thereof. The metal-containing materials include at least one of a metal or metal alloy such as titanium (Ti), aluminum (Al), aluminum neodymium (AlNd), molybdenum (Mo), molybdenum tungsten (MoW), copper (Cu), or combinations thereof. The inorganic materials of the first structure 110A and the second structure 110B may include a silicon nitride (Si₃N₄) material, a silicon oxide (SiO₂) material, a silicon oxynitride (Si₂N₂O) material, or combinations thereof. The overhang structures 110 are able to remain in place, i.e., are permanent. Thus, the overhang structures are not lifted off during formation of the device, and the overhang structures do not leave behind organic material that may disrupt OLED performance. Eliminating the need for a lift-off procedure also increases throughput during forming of devices.

In one example, the second structure 110B includes a non-conductive inorganic material and the first structure 110A includes a conductive inorganic material or a metal-containing material. In another example, the second structure 110B includes a conductive inorganic material or metal-containing material and the first structure 110A includes a conductive inorganic material or metal-containing material.

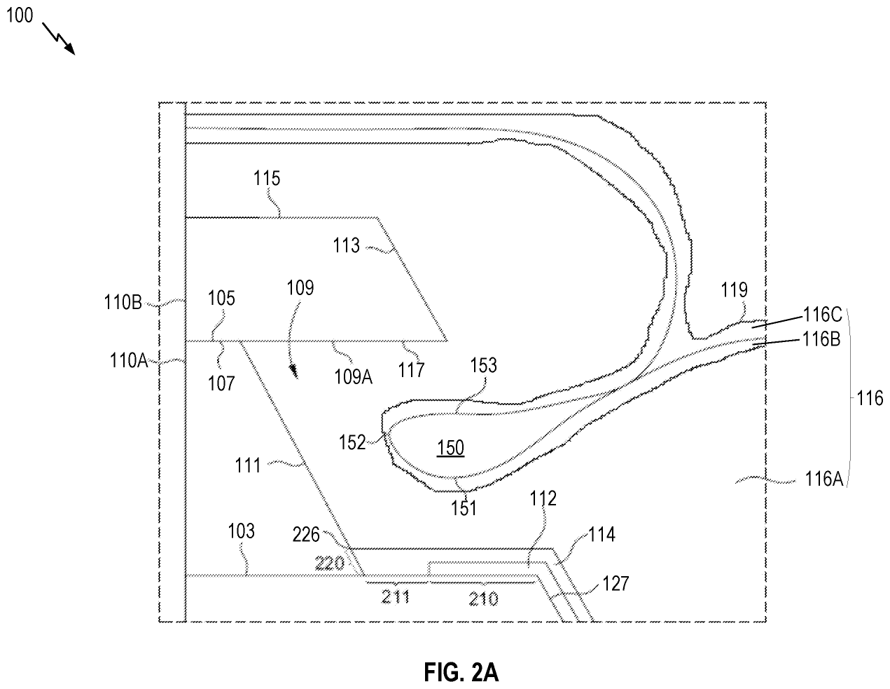

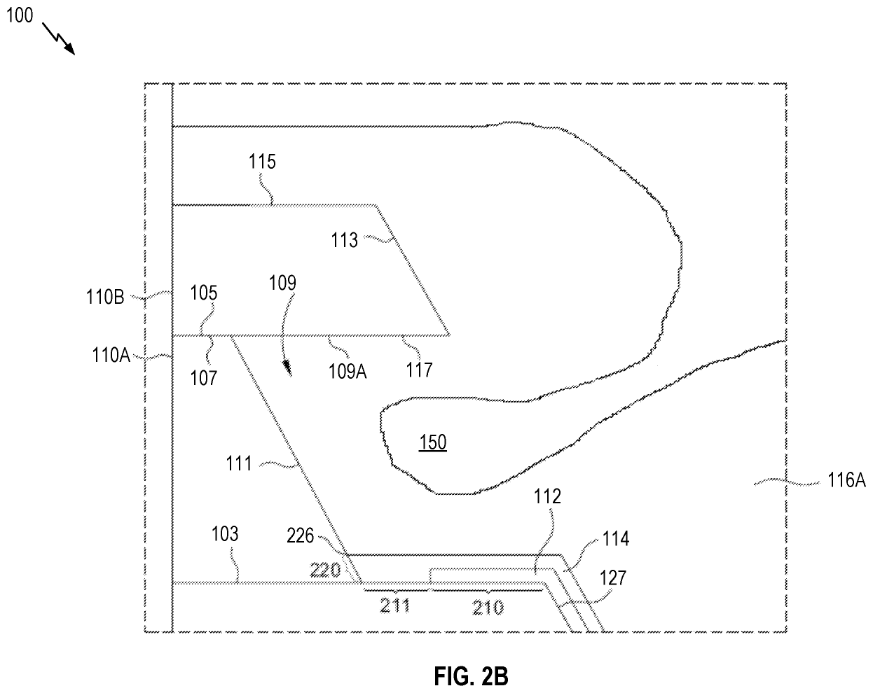

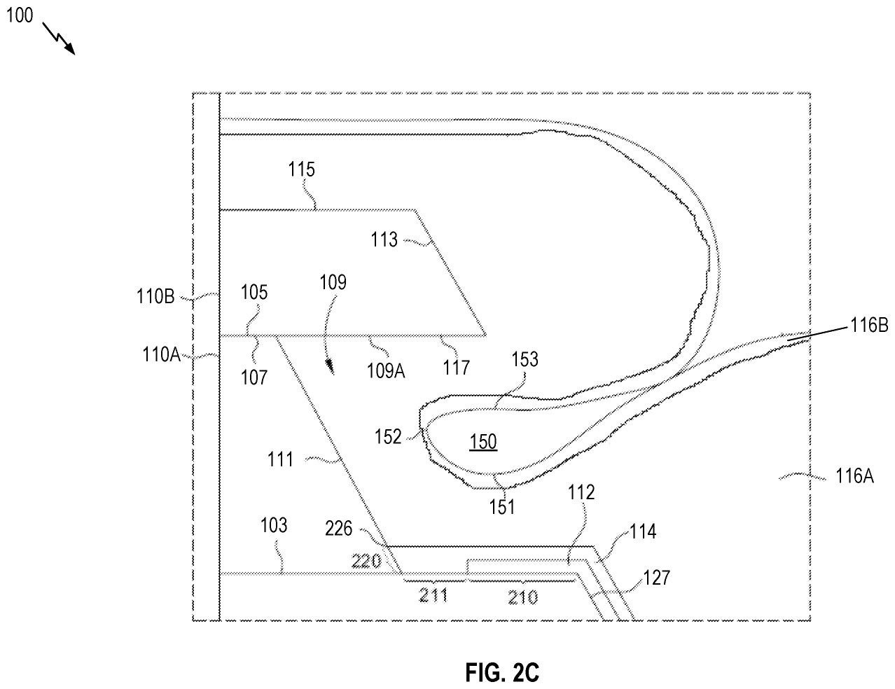

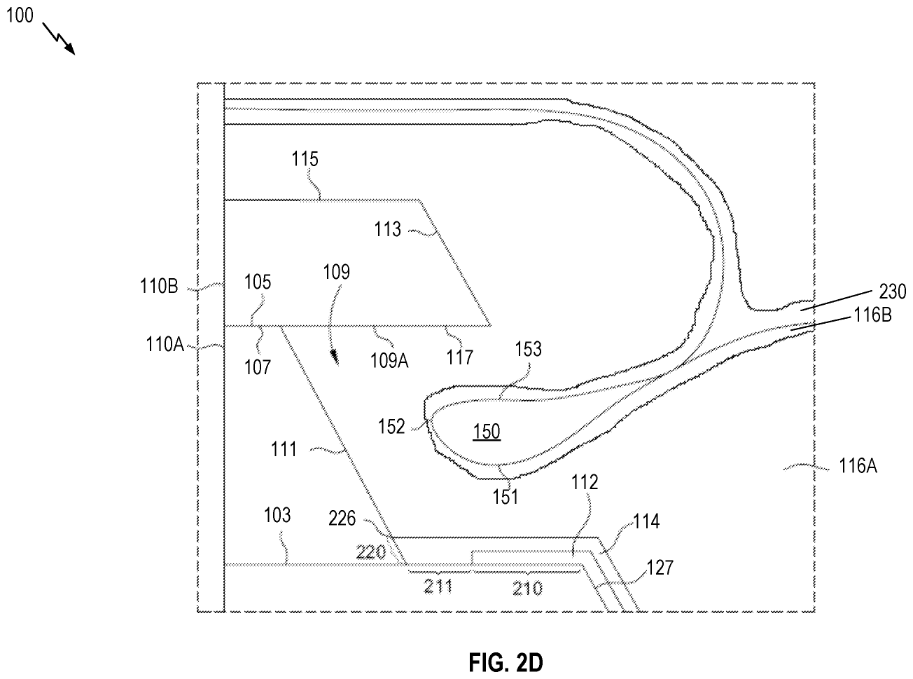

Adjacent overhangs 109 are defined by the top extension 109A of the second structure 110B. At least a bottom surface 107 of the second structure 110B is wider than a top surface 105 of the first structure 110A to form the top extension 109A (as shown in FIG. 1A) of the overhang 109. The second structure 110B is disposed over a top surface 105 of the first structure 110A. The top extension 109A of the second structure 110B forms the overhang 109 and allows for the second structure 110B to shadow the first structure 110A. The shadowing of the overhang 109 provides for evaporation deposition of each of the OLED material 112 and a cathode 114. The OLED material 112 is disposed under the overhang 109. The cathode 114 is disposed over the OLED material 112 and extends under the overhang 109. In one embodiment, as shown in FIG. 2A, the cathode 114 contacts a first portion 220 of the sidewall 111 of the first structure 110A.

The overhang structures 110 provide for a shadowing effect during evaporation deposition with an evaporation angle set by the evaporation source.

In one embodiment, the OLED material 112 and the cathode 114 contact the sidewall 111 of the first structure 110A of the overhang structures 110. In another embodiment, as shown in FIG. 1A, the cathode 114 contacts the sidewall 111 of the first structure 110A of the overhang structures 110. In one embodiment, as shown in FIG. 1A, the encapsulation layer stack 116 is disposed over the sidewall 111 of the first structure 110A and a bottom surface 107 of the second structure 110B. In another embodiment, the cathode 114 contacts busbars (not shown) outside of an active area of the sub-pixel circuit 100. The cathode 114 includes a conductive material, such as a metal or metal alloy. For example, materials of the cathode 114 include, but are not limited to, chromium, titanium, aluminum, ITO, or a combination thereof. In some embodiments, the material of the cathode 114 is different from the material of the first structure 110A and the second structure 110B.

Each sub-pixel 106 includes an encapsulation layer stack 116 including a first layer 116A, a second layer 116B, and a third layer 116C. The encapsulation layer stack 116 may be or may correspond to a local passivation layer. The encapsulation layer stack 116 of a respective sub-pixel is disposed over the cathode 114 (and OLED material 112) with the encapsulation layer stack 116 extending under at least a portion of the overhang structures 110 and over at least a portion of a sidewall of each of the adjacent overhang structures 110.

In an embodiment, as shown in sub-pixel 108a of FIG. 1A, a first layer 116A, a second layer 116B, and a third layer 116C are disposed over the sidewall 111 of the first structure 110A, the bottom surface 107 of the second structure 110B, a sidewall 113 of the second structure 110B, and a portion of a top surface 115 of the second structure 110B of the overhang structures 110. The first layer 116A and second layer 116B have gaps 150. Each of the gaps 150 is defined by a first portion 151, a second portion 152, a third portion 153, and the first portion 151 of the second layer 116B contacting the third portion 153 of the second layer 116B. The first portion 151 of the second layer is disposed over the portion of the first layer 116A that is disposed over the cathode 114. In some embodiments, the first layer 116A contacts the cathode 114. The second portion 152 of the second layer 116B is disposed over the portion of the first layer 116A that is disposed over the sidewall 111 of the first structure 110A. In some embodiments, the first layer 116A contacts the sidewall 111 of the first structure 110A. The third portion 153 of the second layer 116B is disposed under a portion of the first layer 116A that is under an underside surface 117 of the top extension 109A of the second structure 110B. In some embodiments, the first layer 116A contacts the underside surface 117 of the top extension 109A of the second structure 110B. The first portion 151 of the second layer 116B contacts the third portion 153 of the second layer 116B. The gaps 150 are sealed by the contact of the first portion 151 and the third portion 153. The first layer 116A has an inner surface 155. The inner surface 155 contacts the cathode 114, the sidewall 111 of the first structure 110A, and the underside surface 117 of the top extension 109A of the second structure 110B. The second layer 116B has an outer surface 156. The outer surface 156 encloses void spaces outside the second layer 116B. The void spaces correspond to the gaps 150. In one or more embodiments, the gaps 150 and the voids have a size less than the height of the overhang 109. In one or more embodiments, the gaps 150 and the voids have a size less than 1.5 μm, such as less than 0.5 μm.

In some embodiments, as shown in second sub-pixel 108b of FIG. 1A, the first layer 116A, second layer 116B, and third layer 116C are disposed over the sidewall 111 of the first structure 110A, the bottom surface 107 of the second structure 110B, the sidewall 113 of the second structure 110B, and a portion of the top surface 115 of the second structure 110B of the overhang structures 110. The second layer 116B has the gaps 150. Each of the gaps 150 is defined by the first portion 151, the second portion 152, the third portion 153, and the first portion 151 of the second layer 116B contacting the third portion 153 of the second layer 116B. The first portion 151 of the second layer 116B is disposed over a portion of the first layer 116A that is disposed over the cathode 114. In some embodiments, the first layer 116A contacts the cathode 114. The second portion 152 of the second layer 116B is disposed over another portion of the first layer 116A that is disposed over the sidewall 111 of the first structure 110A. In some embodiments, the first layer 116A contacts the sidewall 111 of the first structure 110A. The third portion 153 of the second layer 116B is disposed under another portion of the first layer 116A that is disposed under the underside surface 117 of the top extension 109A of the second structure 110B. In some embodiments, the first layer 116A contacts the underside surface 117 of the top extension 109A of the second structure 110B. The first portion 151 of the second layer 116B contacts the third portion 153 of the second layer 116B. The gaps 150 are sealed by the contact of the first portion 151 and the third portion 153. The first layer 116A has the inner surface 155. The inner surface 155 contacts the cathode 114, the sidewall 111 of the first structure 110A, and the underside surface 117 of the top extension 109A of the second structure 110B. The second layer 116B has the outer surface 156. The outer surface 156 encloses the void spaces outside the second layer 116B. The void spaces correspond to the gaps 150.

In some embodiments, the portion of the top surface 115 of the second structure 110B that the encapsulation layer stack 116, of the first sub-pixel 108a, is disposed over is separated from the portion of the top surface 115 of the second structure 110B that the encapsulation layer stack 116, of the second sub-pixel 108b, is disposed over. A space 160 therefore exists between the encapsulation layer stack 116 of the first sub-pixel 108a and the encapsulation layer stack 116 of the second sub-pixel 108b, as shown in FIG. 1A. In some embodiments, the encapsulation layer stack 116 of the first sub-pixel 108a overlaps with the encapsulation layer stack 116 of the second sub-pixel 108b.

In some embodiments, as shown in third sub-pixel 108c of FIG. 1A, the encapsulation layer stack 116 is disposed over the sidewall 111 of the first structure 110A, the bottom surface 107 of the second structure 110B, the sidewall 113 of the second structure 110B, and the portion of the top surface 115 of the second structure 110B of the overhang structures 110. The first layer 116A and second layer 116B have the gaps 150. Each of the gaps 150 is defined by the first portion 151, the second portion 152, the third portion 153, and the first portion 151 of the second layer 116B contacting the third portion 153 of the second layer 116B. The first portion 151 of the second layer 116B is disposed over a portion of the first layer 116A that is disposed over the cathode 114. In some embodiments, the first layer 116A contacts the cathode 114. The second portion 152 of the second layer 116B is disposed over a portion of the first layer 116A that is disposed over the sidewall 111 of the first structure 110A. In some embodiments, the first layer 116A contacts the sidewall 111 of the first structure 110A. The third portion 153 of the second layer 116B is disposed under the portion of the first layer 116A that is disposed under the underside surface 117 of the top extension 109A of the second structure 110B. In some embodiments, the first layer 116A contacts the underside surface 117 of the top extension 109A of the second structure 110B. The first portion 151 of the second layer 116B contacts the third portion 153 of the second layer 116B. The gaps 150 are sealed by the contact of the first portion 151 and the third portion 153. The third layer 116C has the inner surface 155 and the outer surface 156. The inner surface 155 contacts the cathode 114, the sidewall 111 of the first structure 110A, and the underside surface 117 of the top extension 109A of the second structure 110B. The outer surface 156 encloses the void spaces outside the third layer 116C. The void spaces correspond to the gaps 150.

In some embodiments, the portion of the top surface 115 of the second structure 110B that the encapsulation layer stack 116, of the second sub-pixel 108b, is disposed over is separated from the portion of the top surface 115 of the second structure 110B that the encapsulation layer stack 116, of the third sub-pixel 108c, is disposed over. A space 160 therefore exists between the encapsulation layer stack 116 of the second sub-pixel 108b and the encapsulation layer stack 116 of the third sub-pixel 108c. In some embodiments, the encapsulation layer stack 116 of the second sub-pixel 108b overlaps with the encapsulation layer stack 116 of the third sub-pixel 108c, as shown in FIG. 1A.

In embodiments including one or more capping layers, the capping layers are disposed between the cathode 114 and the encapsulation layer stack 116. For example, a first capping layer and a second capping layer are disposed between the cathode 114 and the encapsulation layer stack 116. Each of the embodiments described herein may include one or more capping layers disposed between the cathode 114 and the encapsulation layer stack 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer 120 disposed over the overhang structure 110 and the encapsulation layer stack 116. In yet another embodiment, the sub-pixel includes an intermediate layer 118 (e.g., an intermediate passivation layer) disposed over the overhang structures 110 of each of the sub-pixels 106, and disposed between the encapsulation layer stack 116 and the global passivation layer 120.

The arrangement 101A of the sub-pixel circuit 100 further include at least a global passivation layer 120 disposed over the overhang structures 110 and the encapsulation layer stacks 116. In one embodiment, an intermediate layer 118 may be disposed between the global passivation layer 120 and the overhang structures 110 and the encapsulation layer stacks 116. The intermediate layer 118 may include an inkjet material, such as an acrylic material.

FIG. 1B is a schematic, top sectional view of a sub-pixel circuit 100 having a dot-type architecture 101B. FIG. 1C is a schematic, cross-sectional view of a sub-pixel circuit 100 having a line-type architecture 101C. Each of the top sectional views of FIG. 1B and 1C are taken along section line 1′-1′ of FIG. 1A. The dot-type architecture 101B may include a plurality of pixel openings 124A from adjacent PDL structures 126. Each of the pixel openings 124A is surrounded by overhang structures 110, as shown in FIG. 1A, that defines each of the sub-pixels 106 of the dot-type architecture 101B. The line-type architecture 101C may include a plurality of pixel openings 124B from adjacent PDL structures 126. Each of the pixel openings 124B is abutted by overhang structures 110, as shown in FIG. 1A, that define each of the sub-pixels 106 of the line-type architecture 101C.

FIG. 2A is a schematic, cross-sectional view of an overhang structure 110 of a sub-pixel circuit 100 with an encapsulation layer stack 116 including a first layer 116A, a second layer 116B, and a third layer 116C. In one embodiment, the overhang structures 110 include a second structure 110B of a non-conductive inorganic material and a first structure 110A of a conductive inorganic material. In another embodiment, the overhang structures 110 including the second structure 110B of a conductive inorganic material and the first structure 110A of a conductive inorganic material. In one embodiment, the cathode 114 contacts the first structure 110A of the overhang structures 110. In another embodiment, as shown in FIG. 2A, the encapsulation layer stack 116 has the gaps 150. Each of the gaps 150 is defined by the first portion 151, the second portion 152, the third portion 153, and the first portion 151 of the second layer 116B contacting the third portion 153 of the second layer 116B. As illustrated, materials of the third layer 116C are blocked from entering the gap 150 by the second layer 116B. During formation of the encapsulation layer stack 116, the gap 150 remains after the third layer 116C has been formed. The first portion 151 of the encapsulation layer stack 116 is disposed over the cathode 114. In some embodiments, the first portion 151 contacts the cathode 114. The second portion 152 of the encapsulation layer stack 116 is disposed over the sidewall 111 of the first structure 110A. In some embodiments, the second portion 152 contacts the sidewall 111 of the first structure 110A. The third portion 153 of the encapsulation layer stack 116 disposed under the underside surface 117 of the top extension 109A of the second structure 110B. In some embodiments, the third portion 153 contacts the underside surface 117 of the top extension 109A of the second structure 110B. The first portion 151 of the encapsulation layer stack 116 contacts the third portion 153 of the encapsulation layer stack 116. The gaps 150 are sealed by the contact of the first portion 151 and the third portion 153.

The second structure 110B includes an underside edge 206 and an overhang vector 208. The underside edge 206 extends past the sidewall 111 of the first structure 110A. The overhang vector 208 may be defined by the underside edge 206 and the PDL structure 126. In an embodiment, the OLED material 112 may be disposed over the metal-containing layer 104, over the sidewall 127 of the PDL structure 126, and over a first portion 210 of the upper surface 103 of the PDL structure 126, extending under the overhang 109 to an OLED endpoint 218. The OLED material 112 may form an OLED angle θ_{OLED} between an OLED vector 212 and the overhang vector 208. The OLED vector 212 is defined by an OLED endpoint 218 extending under the second structure 110B and the underside edge 206 of the second structure 110B. In one embodiment, the OLED material 112 may include one or more of a HIL, a HTL, an EML, and an ETL.

In an embodiment, the cathode 114 may be disposed over the OLED material 112, over the first portion 210 of the PDL structure 126, and over a second portion 211 of the upper surface 103 of the PDL structures 126 in each sub-pixel 106. In some embodiments, which can be combined with other embodiments described herein, the cathode 114 is disposed on a first portion 220 of the sidewall 111 of the first structure 110A.

The encapsulation layer stack 116 is disposed over the cathode 114 (and OLED material 112) with the encapsulation layer stack 116 extending at least under the second structure 110B of the overhang structure 110 and over at least a portion of a sidewall of the overhang structure 110. In one embodiment, as shown in sub-pixels 108a, 108b, and 108c of FIG. 1A, the encapsulation layer stack 116 of the sub-pixel 108b and the encapsulation layer stack 116 of the third sub-pixel 108c are disposed over the cathode 114 and extend under the adjacent overhangs 109 to contact a second portion (not shown) of the sidewall 111 of the first structure 110A. In an embodiment, as shown in FIG. 2A, the first layer 116A contacts the sidewall 111 of the first structure 110A, the bottom surface 107 of the second structure 110B, a sidewall 113 of the second structure 110B, and a portion of a top surface 115 of the second structure 110B of the overhang structures 110. The encapsulation layer stack 116 further includes a top surface 119 that defines the uppermost edge of the encapsulation layer stack 116 between the sidewalls 111 of the first structure 110A.

In embodiments, the encapsulation layer stack 116 includes a non-conductive inorganic material, such as a silicon-containing material. The silicon-containing material may include a silicon nitride (e.g., Si₃N₄) material, a silicon oxynitride (e.g., Si₂N₂O) material, a silicon oxide (e.g., SiO₂) material, or a combination thereof. In one embodiment, the encapsulation layer stack 116 of the first sub-pixel 108a includes a silicon nitride material, the encapsulation layer stack 116 of the second sub-pixel 108b includes a silicon oxynitride material, and the encapsulation layer stack 116 of the third sub-pixel 108c includes a silicon oxide material. The thicknesses of the encapsulation layer stacks 116 may depend on the etch selectivity of the material of the encapsulation layer stacks 116. The silicon-containing materials can further be varied to change the optical properties of the encapsulation layer stacks 116. For example, the silicon-containing materials can be tuned to increase or decrease the refractive index. The difference in refractive index can also effect the etching rates of the encapsulation layer stacks 116. This allows for additional etch selectivity control of the encapsulation layer stacks 116. In one embodiment, the encapsulation layer stack 116 of the first sub-pixel 108a has a first refractive index, the encapsulation layer stack 116 of the second sub-pixel 108b has a second refractive index, and the encapsulation layer stack 116 of the third sub-pixel 108c has a third refractive index. In this embodiment, the first refractive index, the second refractive index, and the third refractive index are different from each other.

In one embodiment, at least one of the encapsulation layer stack 116 of the first sub-pixel 108a, the encapsulation layer stack 116 of the second sub-pixel 108b, and the encapsulation layer stack 116 of the third sub-pixel 108c may include at least two layers of the silicon-containing material. At least one of the encapsulation layer stack 116 of the first sub-pixel 108a, the encapsulation layer stack 116 of the second sub-pixel 108b, and the encapsulation layer stack 116 of the third sub-pixel 108c includes a composition for at least one of the layers of the silicon-containing material that is different from the compositions of the other encapsulation layer stacks 116. In a first example, the encapsulation layer stack 116 of the first sub-pixel 108a includes a silicon oxynitride material over a silicon nitride material. The encapsulation layer stack 116 of the second sub-pixel 108b includes a silicon oxide material over a silicon nitride material. The encapsulation layer stack 116 of the third sub-pixel 108c includes a silicon nitride material over a silicon oxide material. In a second example, the encapsulation layer stack 116 of the first sub-pixel 108a includes a silicon oxide material over a silicon oxynitride material. The encapsulation layer stack 116 of the second sub-pixel 108b includes a silicon nitride material over a silicon oxynitride material. The encapsulation layer stack 116 of the third sub-pixel 108c has a silicon oxynitride material over a silicon oxide material.

The encapsulation layer stacks 116 may further be varied using different modes of deposition, e.g., atomic layer deposition (ALD), chemical vapor deposition (CVD), and physical vapor deposition (PVD). In one example, the first sub-pixel 108a includes a silicon nitride material deposited using CVD and a silicon oxide material deposited using ALD. The second sub-pixel 108b includes a silicon nitride material deposited using CVD and a silicon oxynitride material deposited using CVD. The third sub-pixel 108c includes a silicon nitride material deposited using CVD. The encapsulation layer stacks 116 may further be varied between using an inductively coupled plasma (IDP) or a conductively coupled plasma (CCP) for the deposition processes.

By varying the encapsulation layer stack 116 compositions, deposition methods, and thicknesses, the encapsulation layer stack 116 in each sub-pixel protects deposited layers during later processing and improves process yield and efficiency. The variation in encapsulation layer stack 116 thicknesses further controls the distance between the underside edge 206 and the top surface of the encapsulation layer stack 116, as shown in sub-pixels 108b and 108c in FIG. 1A. The distances control the amount of etching and deposition that occurs under the overhang structures 110, leading to increased OLED material 112 protection during subsequent deposition and etching.

In some embodiments, the first layer 116A may have a thickness between about 0.5 μm and 1.0 μm, the second layer 116B may have a thickness between about 0.03 μm and 0.1 μm, and the third layer 116C may have a thickness between about 0.3 μm and 0.5 μm. In such embodiments, the encapsulation layer stack 116 may have a total thickness of about 1 μm.

In some embodiments, the first layer 116A may be formed from a silicon nitride material, a silicon oxynitride material, a combination thereof, or other materials. The first layer 116A may deposited by a plasma-enhanced chemical vapor deposition (PECVD) process.

In some embodiments, the second layer 116B may be formed from hexamethyldisiloxane (HMDSO) or other materials. The second layer 116B may deposited by an ALD process.

In some embodiments, the third layer 116C may be formed from a silicon nitride material, a silicon oxynitride material, a combination thereof, or other materials. The third layer 116C may deposited by a plasma-enhanced chemical vapor deposition (PECVD) process.

During evaporation deposition of the OLED material 112, the underside edge 206 of the second structure 110B defines the position of the OLED endpoint 218. E.g., the OLED material 112 is evaporated at an OLED maximum angle that corresponds to the OLED vector 212 and the underside edge 206 ensures that the OLED material 112 is not deposited past the OLED endpoint 218. During evaporation deposition of the cathode 114, the underside edge 206 of the second structure 110B defines the position of the cathode endpoint 226. E.g., the cathode 114 is evaporated at a cathode maximum angle that corresponds to the cathode vector 224 and the underside edge 206 ensures that the cathode 114 is not deposited past the cathode endpoint 226. The OLED angle % LED is less than the cathode angle θ_{cathode}.

FIG. 2B is a schematic, cross-sectional view of an overhang structure 110 of a sub-pixel circuit 100 with a first layer 116A of an encapsulation layer stack 116. That is, FIG. 2B shows the same sub-pixel circuit 100 as shown in FIG. 2A, except the encapsulation layer stack is still being formed, and the second layer 116B (see FIGS. 2A and 2C) and the third encapsulation layer (see FIG. 2A) have not been formed on the sub-pixel circuit 100. Features in FIG. 2B that have previously been described herein are not further described. As illustrated, as the first layer 116A is formed on the sub-pixel circuit 100, gaps 150 are also formed.

FIG. 2C is a schematic, cross-sectional view of an overhang structure 110 of a sub-pixel circuit 100 with a first layer 116A and a second layer 116B of an encapsulation layer stack 116. That is, FIG. 2C shows the same sub-pixel circuit 100 as shown in FIG. 2A, except the encapsulation layer stack is still being formed, and the third encapsulation layer (see FIG. 2A) has not been formed on the sub-pixel circuit 100. Features in FIG. 2C that have previously been described are not further described. As illustrated, during formation of the sub-pixel circuit 100, the first portion 151 of the second layer 116B contacts the third portion 153 of the second layer 116B and closes the gap left by the first layer 116A. The gap 150 remains after the second layer 116B has been applied.

FIG. 2D is a schematic, cross-sectional view of an overhang structure 110 of a sub-pixel circuit 100 with a first layer 116A and a second layer 116B of an encapsulation layer stack 116 and a resist material layer 230. That is, FIG. 2D shows the same sub-pixel circuit 100 as shown in FIG. 2A, except the third encapsulation layer (see FIG. 2A) has not been formed on the sub-pixel circuit 100, and the resist material layer 230 is present. The resist material layer 230 may be disposed and patterned on the sub-pixel circuit 100 during formation of the sub-pixel circuit 100. Features in FIG. 2D that have previously been described are not further described. The resist material layer 230 is disposed over the second layer 116B. As illustrated, during formation of the sub-pixel circuit 100, the first portion 151 of the second layer 116B contacts the third portion 153 of the second layer 116B and closes the gap left by the first layer 116A. The gap 150 remains after the second layer 116B has been applied.

The resist material may be a positive resist or a negative resist. A positive resist includes portions of the resist material, which, when exposed to electromagnetic radiation, are soluble to a resist developer applied to the resist after the pattern is written into the resist using the electromagnetic radiation. A negative resist includes portions of the resist, which, when exposed to radiation, will be insoluble to the resist developer applied to the resist after the pattern is written into the resist using the electromagnetic radiation. The chemical composition of the resist material determines whether the resist is a positive resist or a negative resist. The resist material layer 230 may be patterned to form one of a pixel opening 124A of the dot-type architecture 101B or a pixel opening 124B of the line-type architecture 101C of one or more of the sub-pixels 108a, 108b, and 108c. The patterning, of the resist material layer 230, may be one of a photolithography process, a digital lithography process, or a laser ablation process.

The first portion 151 of the second layer 116B contacting the third portion 153 of the second layer 116B may prevent the resist material of the resist material layer 230 from entering the gap 150. If the resist material were to enter the gap 150, then the resist material in the gap 150 may remain under the overhang 109, not be exposed to the electromagnetic radiation, and may not be removed (e.g., during an etch operation) during formation of the sub-pixel circuit 100.

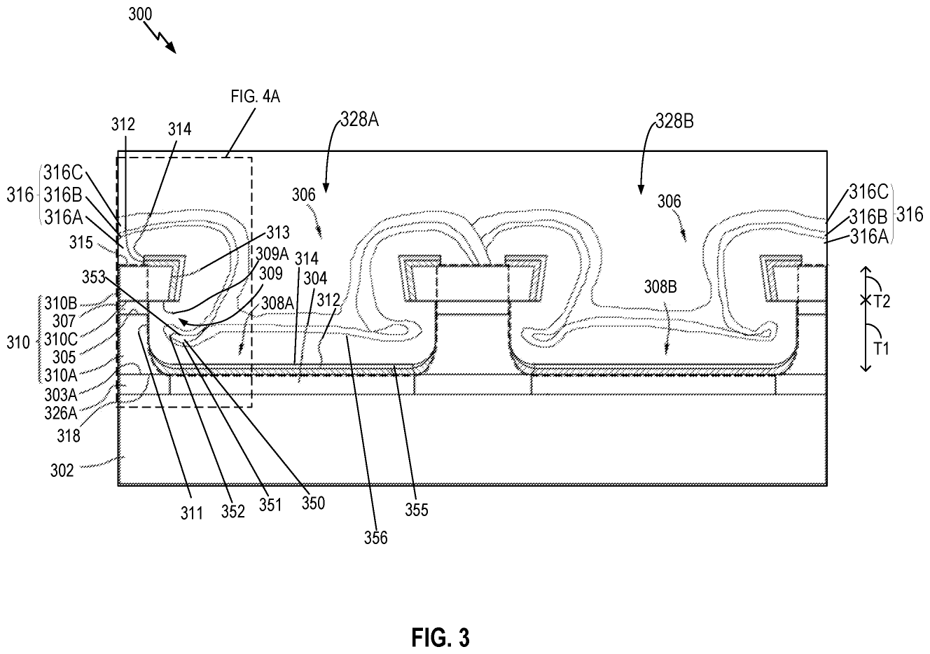

FIG. 3 is a schematic, cross-sectional view of a sub-pixel circuit 300 according to embodiments. The sub-pixel circuit 300 includes a substrate 302. Metal-containing layers (e.g., anodes 304) may be patterned on the substrate 302 and are defined by adjacent anode separation structures 326A disposed on the substrate 302. In one embodiment, the anodes 304 are pre-patterned on the substrate 302. E.g., the substrate 302 is pre-patterned with anodes 304 of indium tin oxide (ITO). The anodes 304 are configured to operate as anodes of respective sub-pixels. In one embodiment, the anode 304 is a layer stack of a first transparent conductive oxide (TCO) layer, a second metal-containing layer disposed on the first TCO layer, and a third TCO layer disposed on the second metal-containing layer. The anodes 304 include, but are not limited to, chromium, titanium, gold, silver, copper, aluminum, ITO, a combination thereof, or other suitably conductive materials. The anodes 304 and the anode separation structures 326A have the same thickness.

The anode separation structures 326A are disposed over the substrate 302. The anode separation structures 326A include one of an organic material, an organic material with an inorganic coating disposed thereon, or an inorganic material. In some embodiments, the anode separation structures 326A may be an electrically insulating polymer. The organic material of the anode separation structures 326A includes, but is not limited to, polyimides. The inorganic material of the anode separation structures 326A includes, but is not limited to, a silicon oxide (SiO₂) material, a silicon nitride (Si₃N₄) material, a silicon oxynitride (Si₂N₂O) material, a magnesium fluoride (MgF₂) material, or combinations thereof. Adjacent anode separation structures 326A define respective sub-pixels and expose the anode 304 of the respective sub-pixel circuit 300.

The sub-pixel circuit 300 has a plurality of sub-pixels 306, including at least a first sub-pixel 308A and second pub-pixel 308B. While FIG. 1 depicts the first sub-pixel 308A and the second sub-pixel 308B, the sub-pixel circuit 300 of the embodiments described herein may include two or more sub-pixels, such as a third sub-pixel and a fourth sub-pixel. Each sub-pixel has OLED materials configured to emit a white, red, green, blue, or other color light when energized. E.g., the OLED materials of the first sub-pixel 308A emits a red light when energized, the OLED materials of the second sub-pixel 308B emits a green light when energized, the OLED materials of a third sub-pixel emits a blue light when energized, and the OLED materials of a fourth sub-pixel emits another color light when energized.

Each sub-pixel 306 includes adjacent overhang structures 310, with adjacent sub-pixels sharing the adjacent overhang structures 310. The overhang structures 310 are permanent to the sub-pixel circuit 300. The overhang structures 310 further define each sub-pixel 306 of the sub-pixel circuit 300. Each overhang structure 310 includes adjacent overhangs 309. The adjacent overhangs 309 are defined by an overhang extension 309A of a second structure 310B extending laterally past an upper surface 305 of a first structure 310A. The first structure 310A is disposed over the anode separation structures 326A, with a lower surface 303A of the first structure 310A contacting an upper surface 318 of the anode separation structures 326A. The second structure 310B is disposed over the first structure 310A. The second structure 310B may be disposed on the upper surface 305 of the first structure 310A. The second structure 310B may also be disposed over an intermediate structure 310C. In some embodiments, the intermediate structure 310C may be disposed over the upper surface 305 of the first structure 310A. The intermediate structure 310C may be an adhesion promotion material. The adhesion promotion material improves adhesion between the first structure 310A and the second structure 310B. The adhesion promotion material may include a chromium (Cr) material. The intermediate structure 310C is an optional layer. The adjacent overhangs 309 include the first structure 310A and the second structure 310B.

In one embodiment, the overhang structures 310 include the second structure 310B of a conductive inorganic material and the first structure 310A of a non-conductive inorganic material. The conductive materials of the second structure 110B may include a gallium arsenide (GaAs) material, a copper (Cu) material, an aluminum (Al) material, an aluminum neodymium (AlNd) material, a molybdenum (Mo) material, a molybdenum tungsten (MoW) material, or combinations thereof. The non-conductive materials of the first structure 310A may include an amorphous silicon (a-Si) material, a titanium (Ti) material, a silicon nitride (Si₃N₄) material, a silicon oxide (SiO₂) material, a silicon oxynitride (Si₂N₂O) material, or combinations thereof. The overhang structures 310 are able to remain in place, i.e., are permanent.

In one embodiment, which may be combined with other embodiments described herein, the first structure 310A includes an inorganic material, such as a silicon material, e.g., an amorphous silicon material, and the second structure 310B includes a germanium material, a copper material, a chromium material, a gallium arsenide (GaAs) material, a group III element material, a group IV element material, a III-V compound material, or a combination thereof. In another embodiment, which may be combined with other embodiments described herein, the first structure 310A includes a germanium material, a copper material, a chromium material, a gallium arsenide (GaAs) material, a group III element material, a group IV element material, a III-V compound semiconductor material, or a combination thereof, and the second structure 310B includes an inorganic material, such as a silicon material, e.g., an amorphous silicon material.

The adjacent overhangs 309 are defined by the overhang extension 309A. At least a bottom surface 307 of the second structure 310B is wider than the upper surface 305 of the first structure 310A to form the overhang extension 309A. The overhang extension 309A of the second structure 310B forms the overhang 309 and allows for the second structure 310B to shadow the first structure 310A. The shadowing of the overhang 309 provides for evaporation deposition of an OLED material 312 and a cathode 314. The OLED material 312 may include one or more of a HIL, a HTL, an EML, and an ETL. The OLED material 312 is disposed over and in contact with the anode 304. The OLED material 312 is disposed under adjacent overhangs 309 and may contact a sidewall 311 of the first structure 310A. In one embodiment, the OLED material 312 is different from the material of the first structure 310A, the second structure 310B, and the intermediate structure 310C. The cathode 314 is disposed over the OLED material 312 and extends under the adjacent overhangs 309. The cathode 314 may extend past an endpoint of the OLED material 312. The cathode 314 may contact the sidewall 311 of the first structure 310A. The overhang structures 310 and an evaporation angle set by an evaporation source define deposition angles, i.e., the overhang structures provide for a shadowing effect during evaporation deposition with the evaporation angle set by the evaporation source.

The cathode 314 includes a conductive material, such as a metal. E.g., the cathode 314 includes, but is not limited to, silver, magnesium, chromium, titanium, aluminum, ITO, or a combination thereof. In one embodiment, material of the cathode 314 is different from the material of the first structure 310A, the second structure 310B, and the intermediate structure 310C. In some embodiments, e.g., as shown in FIG. 3 as applied to the sub-pixel circuit 300, the OLED material 312 and the cathode 314 are disposed over a sidewall 313 of the second structure 310B of the overhang structures 310 in the pixel plane. In other embodiments, the OLED material 312 and the cathode 314 are disposed over an upper surface 315 of the second structure 310B of the overhang structures 310 in the pixel plane. In still other embodiments, the OLED material 312 and the cathode 314 end on the sidewall 311 of the first structure 310A, i.e., are not disposed over the sidewall 313 of the second structure 310B or the upper surface 315 of the second structure 310B in the pixel plane.

Each sub-pixel 306 includes an encapsulation layer stack 316 including a first layer 316A, a second layer 316B, and a third layer 316C. The encapsulation layer stack 116 may be or may correspond to a local passivation layer. The encapsulation layer stack 316 of a respective sub-pixel is disposed over the cathode 314 (and OLED material 312) with the encapsulation layer stack 316 extending under at least a portion of each of the overhangs 309 and along a sidewall 311 of each of the first structure 310A and the second structure 310B. The encapsulation layer stack 316 is disposed over the cathode 314 and extends at least to contact the cathode 314 over the sidewall 311 of the first structure 310A in the pixel plane. In some embodiments, the encapsulation layer stack 316 extends to contact the sidewall 311 of the first structure 310A. In the illustrated embodiments as shown in FIG. 3, the encapsulation layer stack 316 extends to contact the second structure 310B at an underside surface of the overhang extension 309A, the sidewall 313 of the second structure 310B, and the upper surface 315 of the second structure 310B. The encapsulation layer stack 316 includes a conductive inorganic material, such as aluminum oxide (Al₂O₃).

The first layer 316A and second layer 316B have gaps 350. Each of the gaps 350 is defined by a first portion 351, a second portion 352, a third portion 353, and the first portion 351 contacting the third portion 353 of the second layer 316B. The first portion 351 of the second layer 316B contacts the third portion 353 of the second layer 316B. The gaps 350 are sealed by the contact of the first portion 351 and the third portion 353. The first layer 316A has an inner surface 355. The inner surface 355 contacts the cathode 314, the sidewall 311 of the first structure 310A, and the underside surface of the overhang extension 309A of the second structure 310B. The second layer 316B has an outer surface 356. The outer surface 356 encloses void spaces outside the second layer 316B. The void spaces correspond to the gaps 350. In one or more embodiments, the gaps 350 and the voids have a size less than the height of the overhang 309. In one or more embodiments, the gaps 350 and the voids have a size less than 1.5 μm, such as less than 0.5 μm.

In some embodiments, the encapsulation layer stack 316 of the first sub-pixel 308a overlaps with the encapsulation layer stack 316 of the second sub-pixel 308b.

In some embodiments, the first layer 316A may have a thickness between about 0.5 μm and 1.0 μm, the second layer 316B may have a thickness between about 0.03 μm and 0.1 μm, and the third layer 316C may have a thickness between about 0.3 μm and 0.5 μm. In such embodiments, the encapsulation layer stack 316 may have a total thickness of about 1 μm.

In some embodiments, the first layer 316A may be formed from a silicon nitride material, a silicon oxynitride material, a combination thereof, or other materials. The first layer 316A may deposited by a plasma-enhanced chemical vapor deposition (PECVD) process.

In some embodiments, the second layer 316B may be formed from a hexamethyldisiloxane (HMDSO) material or other materials. The second layer 316B may deposited by an ALD process.

In some embodiments, the third layer 316C may be formed from a silicon nitride material, a silicon oxynitride material, a combination thereof, or other materials. The third layer 316C may deposited by a PECVD process.

In embodiments including one or more capping layers, the capping layers are disposed between the cathode 314 and the encapsulation layer stack 316. E.g., a first capping layer and a second capping layer are disposed between the cathode 314 and the encapsulation layer stack 316. Each of the embodiments described herein may include one or more capping layers disposed between the cathode 314 and the encapsulation layer stack 316. The first capping layer may include an organic material. The second capping layer may include an inorganic material, such as lithium fluoride. The first capping layer and the second capping layer may be deposited by evaporation deposition. In another embodiment, the sub-pixel circuit 300 further includes at least a global passivation layer disposed over the overhang structure 310 and the encapsulation layer stack 316. In yet another embodiment, the sub-pixel includes an intermediate passivation layer disposed over the overhang structures 310 of each of the sub-pixels 306, and disposed between the encapsulation layer stack 316 and the global passivation layer.

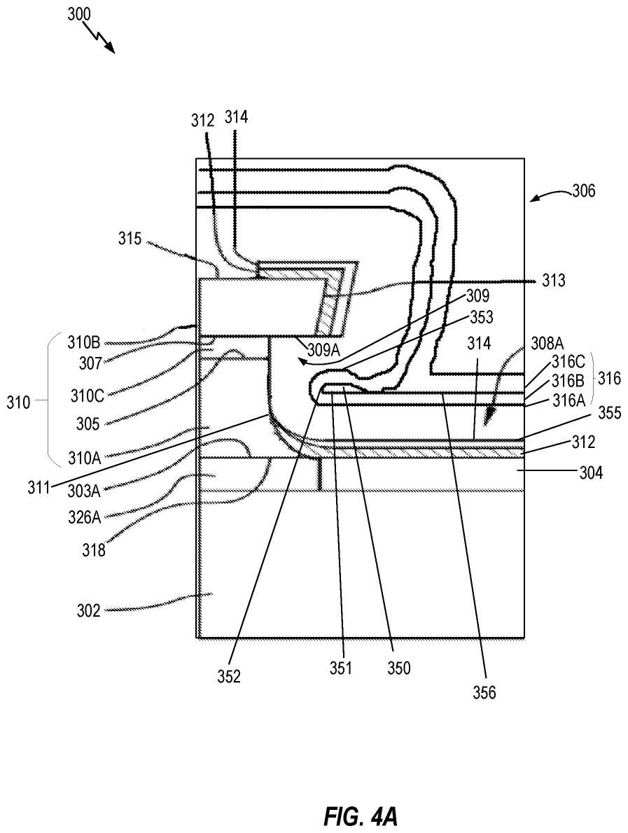

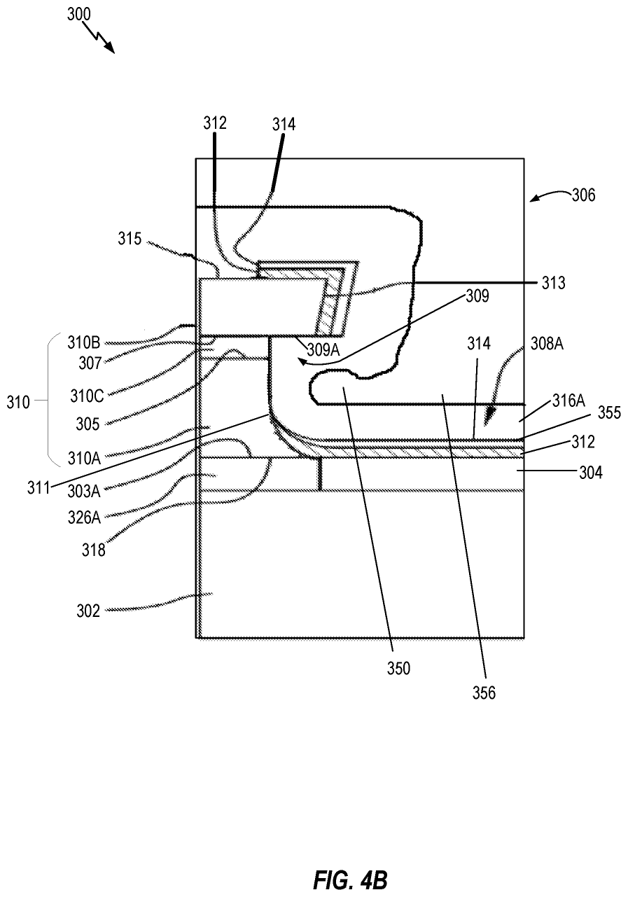

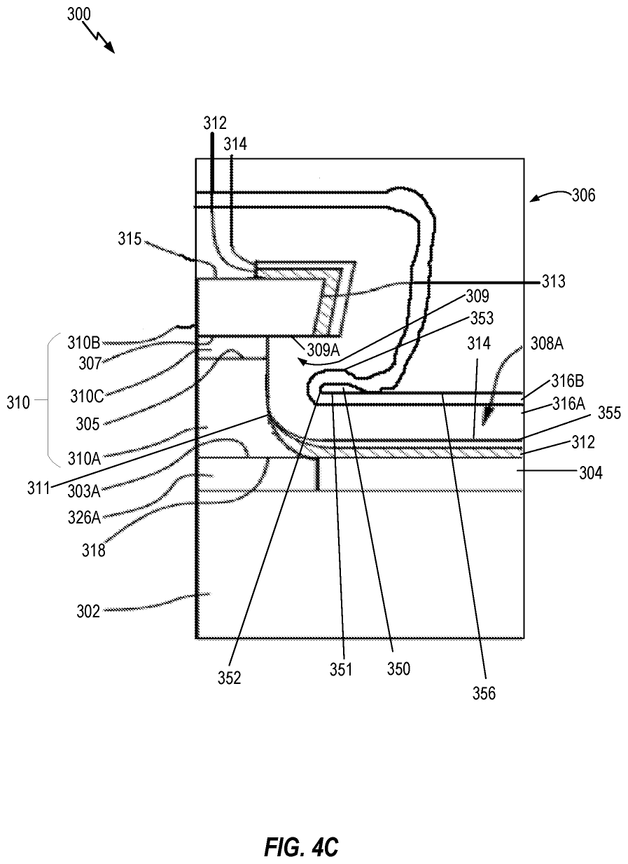

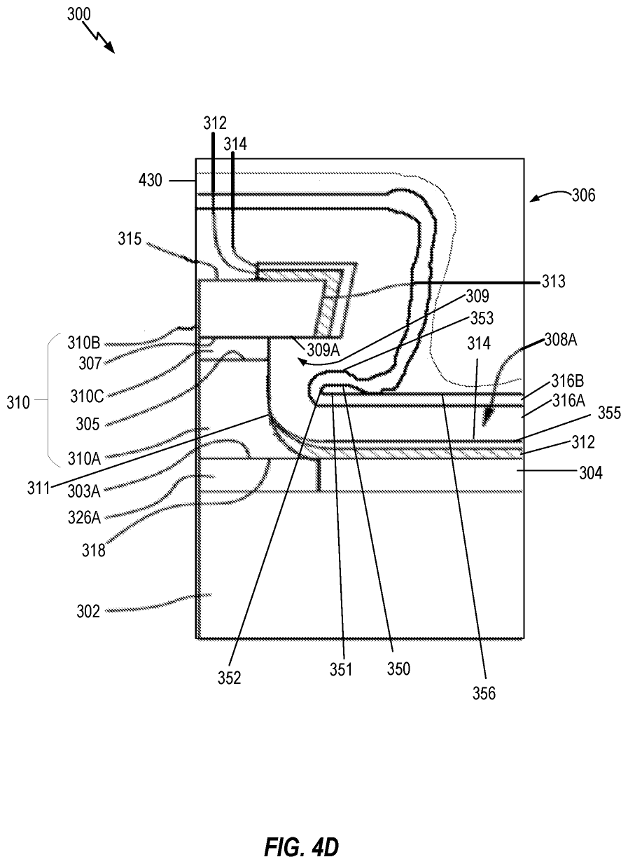

FIG. 4A is an enlarged, schematic, cross-sectional view of the overhang structure 310 of the sub-pixel circuit 300 shown in FIG. 3. The sub-pixel circuit 300 includes the encapsulation layer stack 316 including the first layer 316A, the second layer 316B, and the third layer 316C. Features that have been previously described are not further described. As also shown in FIG. 3, the encapsulation layer stack 316 has the gaps 350. Each of the gaps 350 is defined by the first portion 351, the second portion 352, the third portion 353, and the first portion 351 of the second layer 316B contacting the third portion 353 of the second layer 316B. As illustrated, materials of the third layer 316C are blocked from entering the gap 350 by the second layer 316B. During formation of the encapsulation layer stack 316, the gap 350 remains after the third layer 316C has been formed.

FIG. 4B is an enlarged schematic, cross-sectional view of the overhang structure 310 of the sub-pixel circuit 300 shown in FIGS. 3 and 4A, but without the second layer 316B (see FIGS. 3 and 4A) and the third layer 316C (see FIGS. 3 and 4A). That is, FIG. 4B shows the same sub-pixel circuit 300 as shown in FIG. 3, except the encapsulation layer stack 316 is still being formed, and the second layer 316B (see FIGS. 3 and 4A) and the third layer 316C (see FIGS. 3 and 4A) have not been formed on the sub-pixel circuit 300. Features in FIG. 4B that have previously been described herein are not further described. As illustrated, as the first layer 316A is formed on the sub-pixel circuit 300, gaps 350 are also formed.

FIG. 4C is a schematic, cross-sectional view of the overhang structure 310 of the sub-pixel circuit 300 shown in FIGS. 3, 4A, and 4B, but without the third layer 316C (see FIGS. 3 and 4A). That is, FIG. 4C shows the same sub-pixel circuit 300 as shown in FIG. 3, except the encapsulation layer stack 316 is still being formed, and the third encapsulation layer (see FIGS. 3 and 4A) has not been formed on the sub-pixel circuit 300. Features in FIG. 4C that have previously been described are not further described. As illustrated, during formation of the sub-pixel circuit 300, the first portion 351 of the second layer 316B contacts the third portion 353 of the second layer 316B and closes the gap 350 left by the first layer 316A. The gap 350 remains after the second layer 316B has been applied.

FIG. 4D is a schematic, cross-sectional view of an overhang structure 310 of a sub-pixel circuit 300 with a first layer 316A and a second layer 316B of an encapsulation layer stack 316 and a resist material layer 430. That is, FIG. 4D shows the same sub-pixel circuit 300 as shown in FIG. 3, except the third encapsulation layer (see FIGS. 3 and 4A) has not been formed on the sub-pixel circuit 300, and the resist material layer 430 is present. The resist material of the resist material layer 430 may be disposed and patterned on the sub-pixel circuit 300 during formation of the sub-pixel circuit 300. Features in FIG. 4D that have previously been described are not further described. The resist material layer 430 is disposed over the second layer 316B. As illustrated, during formation of the sub-pixel circuit 300, the first portion 351 of the second layer 316B contacts the third portion 353 of the second layer 316B and closes the gap left by the first layer 316A. The gap 350 remains after the second layer 316B has been applied.

The resist material of the resist material layer 430 may be a positive resist or a negative resist. The chemical composition of the resist material determines whether the resist is a positive resist or a negative resist. The resist material of the resist material layer 430 may be patterned to form one of a pixel opening 124A of the dot-type architecture 101B or a pixel opening 124B of the line-type architecture 101C of one or more of the sub-pixels 308a and 308b. The patterning, of the resist material of the resist material layer 430, may be one of a photolithography process, a digital lithography process, or a laser ablation process.

The first portion 351 of the second layer 316B contacting the third portion 353 of the second layer 316B may prevent the resist material of the resist material layer 430 from entering the gap 350. If the resist material were to enter the gap 350, then resist material in the gap 350 may remain under the overhang 309, not be exposed to the electromagnetic radiation, and may not be removed (e.g., during an etch operation) during formation of the sub-pixel circuit 300.

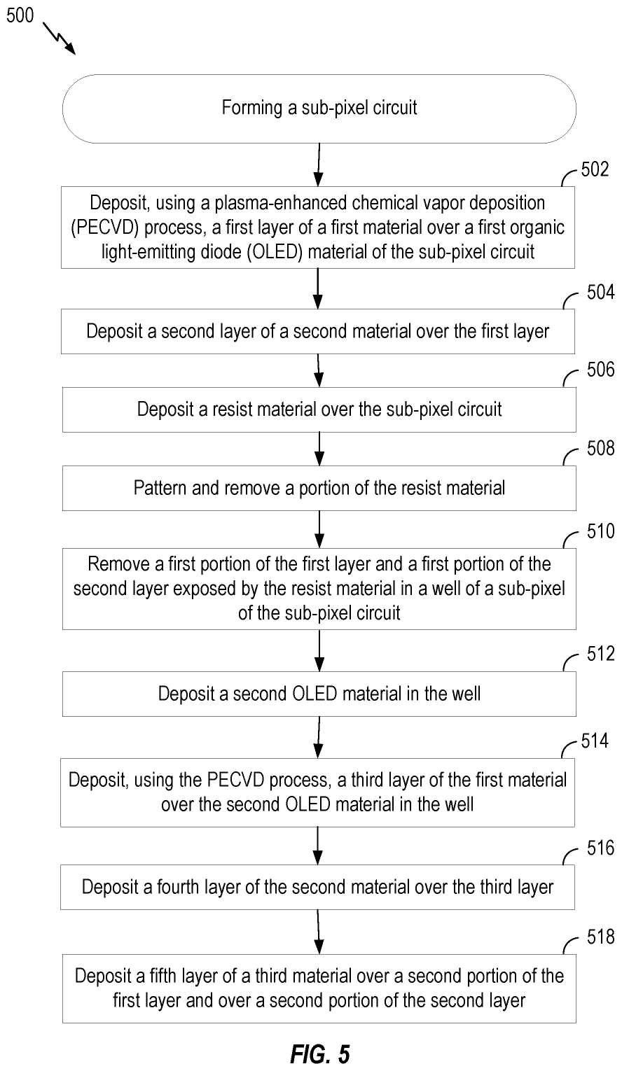

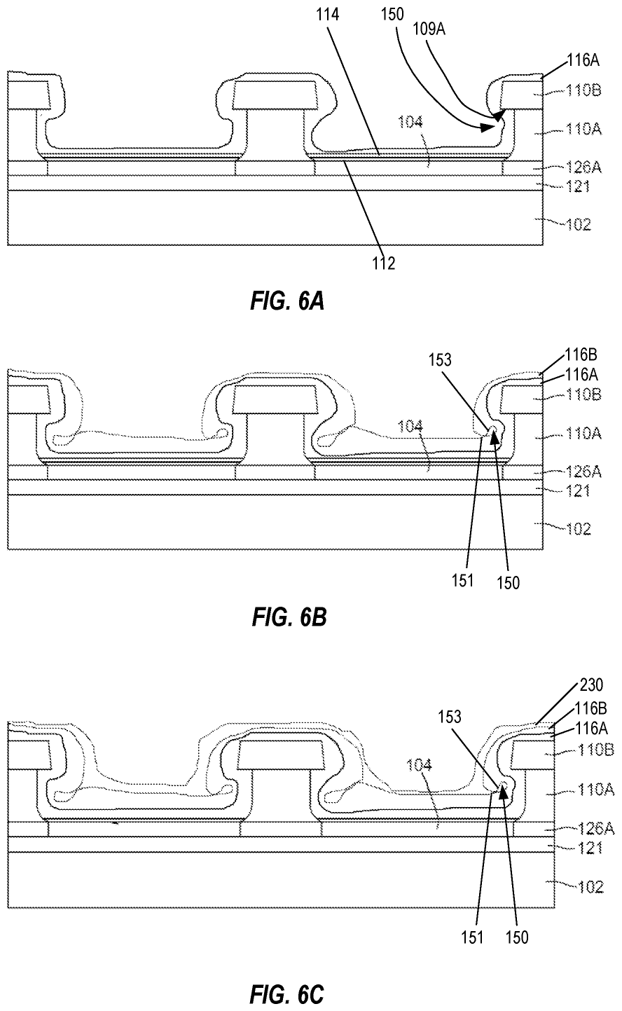

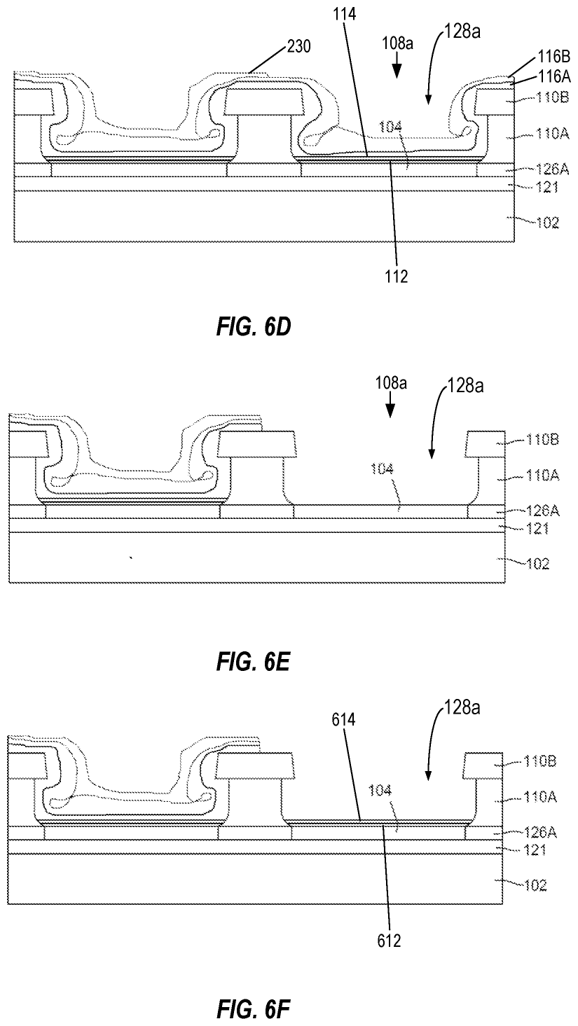

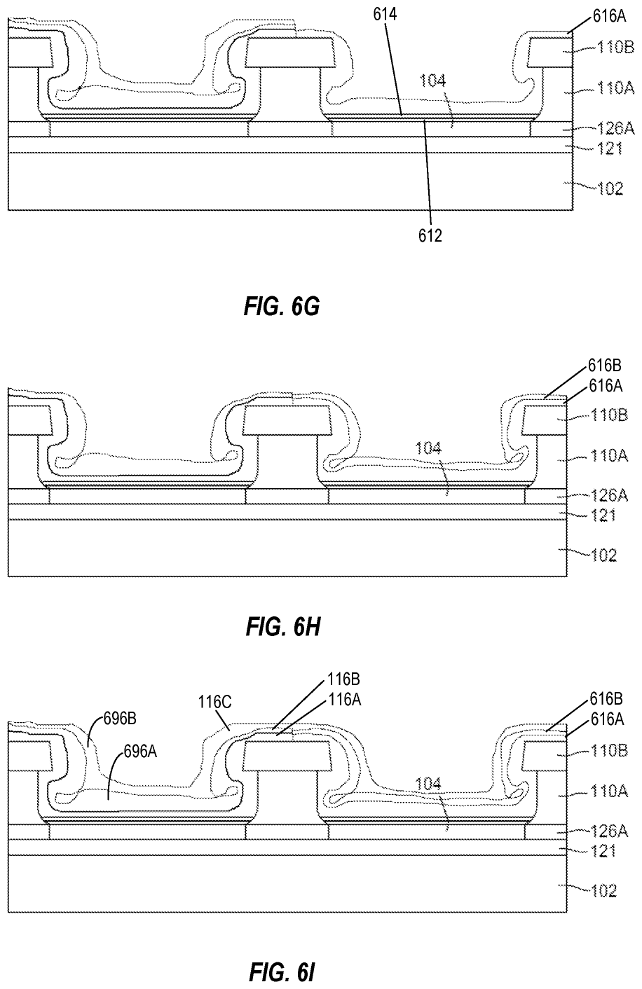

FIG. 5 is a flow diagram of a method 500 for forming sub-pixel circuits 100 or 300, according to embodiments. FIGS. 6A-6I are schematic, cross-sectional views of a substrate 102 during the method 500 for forming the sub-pixel circuits 100 or 300, according to embodiments described herein. The method 500 described herein provides for the ability to fabricate both the sub-pixel circuits 100 and 300 with the dot-type architecture 101B and with the line-type architecture 101C.

At operation 502, a first layer of a first material is deposited, using a plasma-enhanced chemical vapor deposition (PECVD) process, over a first organic light-emitting diode (OLED) material of the sub-pixel circuit. As illustrated in FIG. 6A, the first layer 116A is deposited over the first OLED material 112 and cathode 114 and has a gap 150 under the top extension 109A of the second structure 110B. For example, a first layer 116A is deposited over an OLED material 112 of a sub-pixel circuit 100, as illustrated in FIG. 2B. In another example, the first layer 316A is deposited over the sub-pixel circuit 300, as illustrated in FIG. 4B.

At operation 504, a second layer of a second material is deposited over the first layer. As illustrated in FIG. 6B, the first portion 151 of the second layer 116B contacts the third portion 153 of the second layer 116B and closes off the entrance to the gap 150 in second layer 116B. In an example, a second layer 116B is deposited over the first layer 116A, as illustrated in FIG. 2C. In another example, a second layer 316B is deposited over the first layer 316A, as illustrated in FIG. 4C.

At operation 506, a resist material is deposited over the sub-pixel circuit. As illustrated in FIG. 6C, the resist material 230 is unable to enter the gap 150 because the first portion 151 of the second layer 116B contacts the third portion 153 of the second layer 116B and closes off the entrance to the gap 150 in second layer 116B. In an example, a resist material layer 230 is deposited over the sub-pixel circuit 100, as illustrated in FIG. 2D. Due to the contact of the first portion 151 of the second layer 116B and the third portion 153 of the second layer 116B, the resist material of the resist material layer 230 cannot enter the gaps 150. The resist material of the resist material layer 230 also cannot get underneath the second structure 110B due to the gaps 150 and the encapsulation layer stack 116. In another example, a resist material layer 430 is deposited over the sub-pixel circuit 300, as illustrated in FIG. 4D. Due to the contact of the first portion 351 of the second layer 316B and the third portion 353 of the second layer 316B, the resist material of the resist material layer 430 cannot enter the gaps 350. The resist material of the resist material layer 430 cannot get underneath the second structure 310B due to the gaps 350 and the encapsulation layer stack 316.

At operation 508, a portion of the resist material is patterned and removed. As illustrated in FIG. 6D, a portion of the resist material 230 may be removed above a well 128a of a sub-pixel 108a. In examples, the resist material of the resist material layer 230 or the resist material of the resist material layer 430 may be patterned to form one of a pixel opening 124A of the dot-type architecture 101B, shown in FIG. 1B, or a pixel opening 124B of the line-type architecture 101C, shown in FIG. 1C, of a first sub-pixel 108a. In examples, the patterning may be one of a photolithography, digital lithography process, or laser ablation process. Because the resist materials of the resist material layers 230 and 430 are prevented from moving under the second structures 110B or 310B, the second structures 110B and 310B do not shade the resist materials of the resist material layers 230 and 430, and the resist materials of the resist material layers 230 and 430 may be patterned by exposure to UV light or other radiation.

At operation 510, a first portion of the first layer and a first portion of the second layer exposed by the resist material in a well of a sub-pixel of the sub-pixel circuit are removed. As illustrated in FIG. 6E, a first portion of the first layer 116A and a first portion of the second layer 116B exposed by the resist material 230 above the well 128a of the sub-pixel 108a may be removed. Additionally, a cathode 114 (removed in FIG. 6E and shown in FIG. 6D) and first OLED material 112 (removed in FIG. 6E and shown in FIG. 6D) exposed in the well 128a of the sub-pixel 108a may also be removed. The first portion of the first layer and the first portion of the second layer exposed by the resist material may be removed a dry etch process or a wet etch process. In an example, the first portion of the first layer 116A over the third sub-pixel 108c, shown in FIG. 1A, and the first portion of the second layer 116B over the third sub-pixel 108c may be removed. In the example, a first OLED material may be removed from the well 128c of the third sub-pixel 108c, and a second OLED material may be deposited in the well 128c of the third sub-pixel 108c. In another example, the first portion of the first layer 316A over the second sub-pixel 308B, shown in FIG. 3, and the first portion of the second layer 316B over the second sub-pixel 308B may be removed. In this example, a first OLED material may be removed from the well 328B of the second sub-pixel 308B, and a second OLED material may be deposited in the well 328B of the second sub-pixel 308B.

At operation 512, a second OLED material is deposited in the well. As illustrated in FIG. 6F, a second OLED material 612 may be deposited in the well 128a. The second OLED material 612 may be a different color than the first OLED material 112. Additionally, a metallic material may be deposited to form a cathode 614 in the well 128a. In an example, an OLED material 112 and a metallic material (forming cathode 114) are deposited in the well 128a of the first sub-pixel 108a, as shown in FIG. 1A. In another example, an OLED material 312 and a metallic material (forming cathode 314) are deposited in the well 328A of the first sub-pixel 308A, as shown in FIG. 3.

At operation 514, a third layer of the first material is deposited, using the PECVD process, over the second OLED material in the well. As illustrated in FIG. 6G, the third layer 616A is deposited over the second OLED material 612 and cathode 614. For example, a first layer 116A is deposited over an OLED material 112 of a sub-pixel circuit 100, as illustrated in FIG. 2B. In another example, the first layer 316A is deposited over the sub-pixel circuit 300, as illustrated in FIG. 4B.

At operation 516, a fourth layer of the second material is deposited over the third layer. As illustrated in FIG. 6H, the fourth layer 616B is deposited over the third layer 616A. In an example, a second layer 116B is deposited over the first layer 116A, as illustrated in FIG. 2C. In another example, a second layer 316B is deposited over the first layer 316A, as illustrated in FIG. 4C.

At operation 518, a fifth layer of a third material is deposited over a second portion of the first layer and over a second portion of the second layer. As illustrated in FIG. 6I, the fifth layer 116C is deposited over the second portion 696A of the first layer 116A and the second portion 696B of the second layer 116B. Additionally, the fifth layer 116C may be deposited over the fourth layer 616B. As illustrated, the layer 116C of the third material may form a seamless coating that can act as a passivation layer over a device including the sub-pixel circuit 100. In an example, a fifth layer 116C is deposited over a second portion of the first layer 116A and over a second portion of the second layer 116B in the well of the first sub-pixel 108a, as shown in FIGS. 1A and 2A. In another example, a fifth layer 316C is deposited over a second portion of the first layer 316A and a second portion of the second layer 316B in the well of the first sub-pixel 308A, as shown in FIGS. 3 and 4A.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
a substrate;
adjacent overhang structures defining the sub-pixel;
an anode;
an organic light-emitting diode (OLED) material disposed over the anode;
a cathode disposed over the OLED material; and
an encapsulation layer stack, the encapsulation layer stack having a first layer, a second layer disposed over the first layer, and a third layer, wherein:
the first layer and the second layer have a first portion disposed over the cathode, a second portion disposed over a sidewall of each overhang structure, and a third portion disposed under an underside surface of an extension of each overhang structure;
a gap is defined by contact of the first portion of the second layer and the third portion of the second layer; and
the third layer is disposed over the second layer outside of the gap.

2. The sub-pixel of claim 1, wherein the first layer comprises a silicon nitride (Si₃N₄) material, a silicon oxynitride (Si₂N₂O) material, or a combination thereof.

3. The sub-pixel of claim 1, wherein the second layer comprises a hexamethyldisiloxane (HMDSO) material.

4. The sub-pixel of claim 1, wherein the third layer comprises a silicon nitride (Si₃N₄) material, a silicon oxynitride (Si₂N₂O) material, or a combination thereof.

5. The sub-pixel of claim 1, wherein the OLED material is further disposed under the overhang structures.

6. The sub-pixel of claim 1, wherein one of the overhang structures comprises a first structure and a second structure on the first structure, wherein the second structure has an extension extending laterally past the first structure.

7. The sub-pixel of claim 6, wherein the first structure comprises an inorganic material or a metal-containing material.

8. The sub-pixel of claim 6, wherein the second structure comprises an inorganic material, a non-conductive material, or a metal-containing material.

9. A device, comprising:
a substrate; and
overhang structures defining a plurality of sub-pixels, each sub-pixel comprising:
an anode;
an organic light-emitting diode (OLED) material disposed over the anode;
a cathode disposed over the OLED material; and
an encapsulation layer stack, the encapsulation layer stack having a first layer, a second layer disposed over the first layer, and a third layer, wherein:
the first layer and the second layer have a first portion disposed over the cathode, a second portion disposed over a sidewall of each overhang structure, and a third portion disposed under an underside surface of an extension of each overhang structure;
a gap is defined by contact of the first portion of the second layer and the third portion of the second layer; and
the third layer is disposed over the second layer outside of the gap.

10. The device of claim 9, wherein the first layer comprises a silicon nitride (Si₃N₄) material, a silicon oxynitride (Si₂N₂O) material, or a combination thereof.

11. The device of claim 9, wherein the second layer comprises a hexamethyldisiloxane (HMDSO) material.

12. The device of claim 9, wherein the third layer comprises a silicon nitride (Si₃N₄) material, a silicon oxynitride (Si₂N₂O) material, or a combination thereof.

13. The device of claim 9, wherein one of the overhang structures comprises a first structure and a second structure on the first structure, wherein the second structure has an extension extending laterally past the first structure.

14. The device of claim 9, wherein the OLED material is further disposed under the overhang structures.

15. The device of claim 9, further comprising one or more pixel-defining layer (PDL) structures disposed over the substrate, wherein the PDL structures define sub-pixels of the device.

16. The device of claim 9, further comprising one or more anode separation structures disposed over the substrate, wherein the anode separation structures define the anode.

17. A method of forming a sub-pixel circuit, the method comprising:
depositing, using a plasma-enhanced chemical vapor deposition (PECVD) process, a first layer of a first material over a first organic light-emitting diode (OLED) material of the sub-pixel circuit;
depositing a second layer of a second material over the first layer;
depositing a resist material over the sub-pixel circuit;
patterning and removing a portion of the resist material;
removing a first portion of the first layer and a first portion of the second layer exposed by the resist material in a well of a sub-pixel of the sub-pixel circuit;
depositing a second OLED material in the well;
depositing, using the PECVD process, a third layer of the first material over the second OLED material in the well;
depositing a fourth layer of the second material over the third layer; and
depositing a fifth layer of a third material over a second portion of the first layer and over a second portion of the second layer.

18. The method of claim 17, wherein the sub-pixel is a first sub-pixel and the sub-pixel circuit further comprises a second sub-pixel, and the method further comprising:
depositing the first OLED material in the well of the first sub-pixel and in a second well of the second sub-pixel prior to depositing the first layer of the first material;
removing a first portion of the first OLED material exposed by the resist material from the second well subsequent to patterning the resist material and prior to depositing the third layer of the third material; and
depositing a second OLED material in the second well subsequent to removing the first portion of the first OLED material and prior to depositing the third layer of the third material.

19. The method of claim 18, wherein the sub-pixel circuit further comprises a third sub-pixel, and the method further comprising:
depositing the first OLED material in a third well of the third sub-pixel prior to depositing the first layer of the first material;
removing a third portion of the first OLED material exposed by the resist material from the third well subsequent to patterning the resist material and prior to depositing the third layer of the third material;
depositing another resist material over the sub-pixel circuit subsequent to removing the third portion of the first OLED material;
patterning the other resist material prior to depositing the third layer of the third material;
removing a first portion of the second OLED material exposed by the resist material from the third well subsequent to patterning the other resist material and prior to depositing the third layer of the third material; and
depositing a third OLED material in the third well subsequent to removing the first portion of the second OLED material and prior to depositing the third layer of the third material.

20. The method of claim 17, wherein:
the first material comprises a silicon nitride (Si₃N₄) material, a silicon oxynitride (Si₂N₂O) material, or a combination thereof;
the second material comprises a hexamethyldisiloxane (HMDSO) material; and
the third material comprises the Si₃N₄ material, the Si₂N₂O material, or the combination thereof.
